(19) United States
(12) Patent Application Publication
(10) Pub. No.: US 2024/0373697 A1
(43) Pub. Date: Nov. 7, 2024

(54) DISPLAY DEVICE

(71) Applicant: Samsung Display Co., LTD., Yongin-si (KR)

(72) Inventors: Seok Hyun LIM, Yongin-si (KR); Ju Hoon KANG, Yongin-si (KR); Hyung Keun PARK, Yongin-si (KR); Eun Ho SONG, Yongin-si (KR); Sang Hee JANG, Yongin-si (KR); Joo Hee JEON, Yongin-si (KR); Mi Yeon CHO, Yongin-si (KR); Gun Hee KIM, Yongin-si (KR); Dae Ho SONG, Yongin-si (KR); Sun Young JUNG, Yongin-si (KR)

(21) Appl. No.: 18/630,976

(22) Filed: Apr. 9, 2024

(30) Foreign Application Priority Data
May 3, 2023 (KR) 10-2023-0057904

(51) Int. Cl. H10K 59/131; H10K 59/121; H10K 59/126; H10K 59/38; H10K 59/88; H10K 102/00

(52) U.S. Cl. CPC H10K 59/131; H10K 59/1213; H10K 59/126; H10K 59/38; H10K 59/88; H10K 2102/351

(57) ABSTRACT

A display device includes: a substrate; a first pixel electrode and a second pixel electrode on the substrate; a dummy pixel electrode between the first pixel electrode and the second pixel electrode, and to receive a dummy voltage; an emissive layer on the first pixel electrode, the second pixel electrode, and the dummy pixel electrode; and a common electrode on the emissive layer. The first pixel electrode is to receive a pixel voltage different from the dummy voltage.

### CROSS-REFERENCED TO RELATED APPLICATION

The present application claims priority to and the benefit of Korean Patent Application No. 10-2023-0057904, filed on May 3, 2023, in the Korean Intellectual Property Office, the entire disclosure of which is incorporated by reference herein.

### BACKGROUND

### 1. Field

Aspects of embodiments of the present disclosure relate to a display device, and more particularly, to a display device in which a leakage current between adjacent pixels through side surfaces may be suppressed without a physical structure.

### 2. Description of Related Art

In an ultra-fine pixel structure, a bank for defining emission areas between adjacent pixels has a small width. For example, a micro display using a CMOS driving substrate, such as micro OLEDs and micro LEDs, has a pixel pitch of only several micrometers, and thus, the width of a bank between adjacent pixels is quite small. Therefore, a display device having an ultra-fine pixel structure may be vulnerable to a leakage current through side surfaces via common layers, such as a hole transporting layer and an electron transporting layer. The leakage current through the side surfaces may cause color interference between adjacent pixels, thereby, deteriorating image quality.

The above information disclosed in this Background section is for enhancement of understanding of the background of the present disclosure, and therefore, it may contain information that does not constitute prior art.

### SUMMARY

In order to block the leakage current through the side surfaces, a physical structure, such as a separator that separates a common layer between adjacent pixels, may be used. However, voids may be generated under the separator due to the shape of the separator (e.g., an overhang structure), which may cause problems. For example, such voids may grow over the processes, and the grown voids may propagate to an encapsulation film to damage the encapsulation film.

One or more embodiments of the present disclosure are directed to a display device in which a leakage current between adjacent pixels through side surfaces may be suppressed without a physical structure.

However, the aspects and features of the present disclosure are not limited to those described above, and additional aspects and features of the present disclosure, will be more clearly understood by those having ordinary skill in the art from the following description.

According to one or more embodiments of the present disclosure, a display device includes: a substrate; a first pixel electrode and a second pixel electrode on the substrate; a dummy pixel electrode between the first pixel electrode and the second pixel electrode, and configured to receive a dummy voltage; an emissive layer on the first pixel electrode, the second pixel electrode, and the dummy pixel electrode; and a common electrode on the emissive layer. The first pixel electrode is configured to receive a pixel voltage different from the dummy voltage.

In an embodiment, the dummy voltage may be smaller than the pixel voltage.

In an embodiment, the dummy voltage may be a DC voltage that is higher than a common voltage of the common electrode, and lower than a lowest grayscale level pixel voltage.

In an embodiment, display device may further include a light-blocking layer overlapping with the dummy pixel electrode.

In an embodiment, the dummy pixel electrode may have a shape that surrounds each of the first pixel electrode and the second pixel electrode, and a portion of the dummy pixel electrode may be located between the first pixel electrode and the second pixel electrode.

In an embodiment, the dummy pixel electrode may include: a first extended portion extending in a first direction; and a second extended portion extending in a second direction crossing the first direction.

In an embodiment, the dummy pixel electrode may define a plurality of open areas surrounded by the first extended portion and the second extended portion, and the first pixel electrode and the second pixel electrode may be located in the plurality of open areas.

In an embodiment, at least one of the first extended portion or the second extended portion may include: a wide portion having a first width; and a narrow portion having a second width smaller than the first width.

In an embodiment, a dummy emission area of the dummy pixel electrode may be located on the wide portion.

In an embodiment, a distance between the dummy pixel electrode and the common electrode may be smaller than a distance between the first pixel electrode and the common electrode.

In an embodiment, a thickness of the dummy pixel electrode may be greater than a thickness of the first pixel electrode.

In an embodiment, display device may further include an insulating film between the substrate and the first pixel electrode, the second pixel electrode, and the dummy pixel electrode, and the insulating film may have a greater thickness between the substrate and the dummy pixel electrode than between the substrate and the first pixel electrode.

In an embodiment, display device may further include a bank on the first pixel electrode, the second pixel electrode, and the dummy pixel electrode.

In an embodiment, the bank may have a first emission area, a second emission area, and a dummy emission area overlapping with the first pixel electrode, the second pixel electrode, and the dummy pixel electrode, respectively.

In an embodiment, a size of the dummy emission area may be smaller than a size of the first emission area.

In an embodiment, the dummy emission area may be located on at least one of an upper side, a lower side, a left side, or a right side of the first pixel electrode.

In an embodiment, the dummy emission area may have a shape that surrounds each of the first pixel electrode and the second pixel electrode.

In an embodiment, display device may further include a light-blocking layer overlapping with the dummy emission area.

In an embodiment, display device may further include: a first color filter overlapping with the first emission area; and a second color filter overlapping with the second emission area.

In an embodiment, the emissive layer may include a plurality of light-emitting units configured to emit light of different colors from each other.

According to one or more embodiments of the present disclosure, a display device includes: a substrate; a first pixel electrode and a second pixel electrode on the substrate; a dummy pixel electrode between the first pixel electrode and the second pixel electrode; an emissive layer on the first pixel electrode, the second pixel electrode, and the dummy pixel electrode; a common electrode on the emissive layer; and a light-blocking layer on the dummy pixel electrode.

In an embodiment, the light-blocking layer may overlap with a dummy emission area of the dummy pixel electrode.

In an embodiment, the first pixel electrode may be configured to receive a pixel voltage, and the dummy pixel electrode may be configured to receive a dummy voltage different from the pixel voltage.

In an embodiment, the dummy voltage may be smaller than the pixel voltage.

In an embodiment, the dummy voltage may be a DC voltage that is higher than a common voltage of the common electrode, and lower than a lowest grayscale level pixel voltage.

According to one or more embodiments of the present disclosure, a dummy light-emitting element may be disposed between adjacent light-emitting elements. The dummy light-emitting element may consume a lateral leakage current from adjacent light-emitting elements. Accordingly, color mixing between adjacent pixels due to such leakage current may be prevented or substantially prevented, and thus, image quality may be improved.

According to one or more embodiments of the present disclosure, by suppressing the lateral leakage current by using the electrical circuit configuration (e.g., the dummy light-emitting element) without using a physical structure such as a separator, it may be possible to prevent or reduce the problems that may be caused by the separator, for example, such as damage that may be caused to an encapsulation film due to the voids.

### BRIEF DESCRIPTION OF THE DRAWINGS

The above and other aspects and features of the present disclosure will be more clearly understood from the following detailed description of the illustrative, non-limiting embodiments with reference to the accompanying drawings.

FIG. 1 is a plan view of a display device according to an embodiment of the present disclosure.

FIG. 2 is a perspective view showing a display device included in an electron device according to an embodiment of the present disclosure.

FIG. 3 is a cross-sectional view of the display device of FIG. 2 from the side.

FIG. 4 is a plan view showing a display layer of a display device according to an embodiment of the present disclosure.

FIG. 5 is a plan view of pixel electrodes and a dummy pixel electrode of a display device according to an embodiment.

FIG. 6 is a cross-sectional view taken along the line I-I′ of FIG. 5.

FIG. 7 is a view illustrating current flows in an emission area and a dummy emission area in a display device according to an embodiment.

FIG. 8 is an equivalent circuit diagram in the emission area and the dummy emission area of FIG. 7.

FIG. 9 is a cross-sectional taken along the line I-I′ of FIG. 5.

FIG. 10 is a cross-sectional view taken along the line I-I′ of FIG. 5.

FIG. 11 is a plan view of pixel electrodes and a dummy pixel electrode of a display device according to an embodiment.

FIG. 12 is a plan view of pixel electrodes and a dummy pixel electrode of a display device according to an embodiment.

FIG. 13 is a cross-sectional view showing a structure of a display element according to an embodiment of the present disclosure.

FIGS. 14 through 17 are cross-sectional views illustrating structures of light-emitting elements according to embodiments.

FIG. 18 is a cross-sectional view showing an example of the organic light-emitting diode of FIG. 16.

FIG. 19 is a cross-sectional view showing an example of the organic light-emitting diode of FIG. 17.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

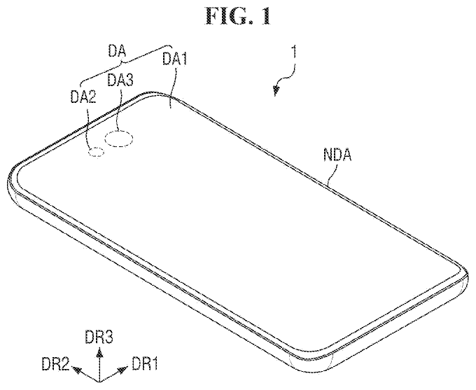

FIG. 1 is a plan view of a display device according to an embodiment of the present disclosure.

Referring to FIG. 1, an electronic device 1 displays a moving image or a still image. The electronic device 1 may refer to any suitable electronic device that provides a display screen. For example, the electronic device 1 may include a television set, a laptop computer, a monitor, an electronic billboard, an Internet of Things device, a mobile phone, a smart phone, a tablet personal computer (PC), an electronic watch, a smart watch, a watch phone, a head-mounted display device, a mobile communications terminal, an electronic notebook, an electronic book, a portable multimedia player (PMP), a navigation device, a game console, a digital camera, a camcorder, and the like.

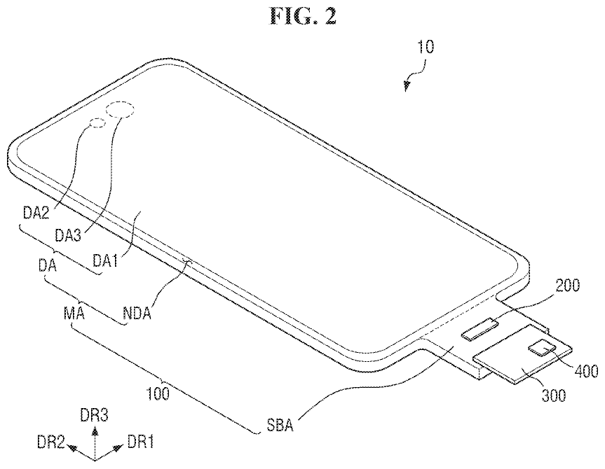

The electronic device 1 may include a display device 10 (e.g., see FIG. 2) for providing the display screen. The display device 10 may include, for example, an inorganic light-emitting diode display device, an organic light-emitting display device, a quantum-dot light-emitting display device, a plasma display device, a field emission display device, and the like. For convenience, an organic light-emitting diode display device is described in more detail hereinafter as a representative example of the display device 10, but the present disclosure is not limited thereto. Any other suitable kind of display device may be included according to embodiments of the present disclosure.

The shape of the electronic device 1 may be modified in various suitable ways. For example, the electronic device 1 may have any suitable shape, such as a rectangle with longer lateral sides, a rectangle with longer vertical sides, a square, a quadrangle with rounded corners (e.g., vertices), other suitable polygons, a circle, an oval, and the like. The shape of a display area DA of the electronic device 1 may be similar to the overall shape of the electronic device 1. In the embodiment illustrated in FIG. 1, the electronic device 1 has a rectangular shape with longer sides extending in a second direction DR2.

The electronic device 1 may include the display area DA and a non-display area NDA. In the display area DA, images may be displayed. In the non-display area NDA, images may not be displayed. The display area DA may be referred to as an active area, and the non-display area NDA may be referred to as an inactive area. The display area DA may generally occupy the center of the electronic device 1.

The display area DA may include a first display area DA1, a second display area DA2, and a third display area DA3. In the second display area DA2 and the third display area DA3, components for adding a variety of suitable features to the electronic device 1 may be disposed. In other words, the second display area DA2 and the third display area DA3 may be referred to as component areas.

FIG. 2 is a perspective view showing a display device included in an electronic device according to an embodiment of the present disclosure.

Referring to FIG. 2, the electronic device 1 (e.g., see FIG. 1) according to an embodiment of the present disclosure may include the display device 10. The display device 10 may provide a display screen where images are displayed in the electronic device 1. The display device 10 may have a shape that is the same or substantially the same as (or similar to) that of the electronic device 1 when viewed from the top (e.g., in a plan view). For example, the display device 10 may have a shape similar to a rectangle having shorter sides extending in the first direction DR1, and longer sides extending in the second direction DR2. The corners where the shorter sides in the first direction DR1 meet the longer sides in the second direction DR2 may be rounded with a suitable curvature (e.g., a predetermined curvature). However, the present disclosure is not limited thereto. For example, the corners may be formed at a right angle. The shape of the display device 10 when viewed from the top (e.g., in a plan view) is not limited to the quadrangular shape, and may be formed in another suitable shape, such as other polygonal shapes, a circular shape, or an elliptical shape.

The display device 10 may include a display panel 100, a display driver 200, a circuit board 300, and a touch driver 400.

The display panel 100 may include a main area MA and a subsidiary area SBA.

The main area MA may include the display area DA including pixels for displaying images, and the non-display area NDA located around (e.g., adjacent to) the display area DA. For example, the non-display area NDA may surround (e.g., around a periphery of) the display area DA. The display area DA may include the first display area DA1, the second display area DA2, and the third display area DA3. The display area DA may emit light from a plurality of emission areas or a plurality of open areas. For example, the display panel 100 may include a pixel circuit including switching elements, a pixel-defining layer that defines the emission areas or the open areas, and a self-light-emitting element.

For example, the self-light-emitting element may include, but is not limited to, at least one of an organic light-emitting diode including an organic emissive layer, a quantum-dot light-emitting diode (quantum LED) including a quantum-dot emissive layer, an inorganic light-emitting diode (inorganic LED) including an inorganic semiconductor, or a micro light-emitting diode (micro LED).

The non-display area NDA may be disposed on an outer side of the display area DA. The non-display area NDA may be defined as an edge area of the main area MA of the display panel 100. The non-display area NDA may include a gate driver that applies gate signals to gate lines, and fan-out lines that connect the display driver 200 with the display area DA.

The subsidiary area SBA may be extended from one side of the main area MA. The subsidiary area SUB may include a flexible material that may be bent, folded, or rolled. For example, when the subsidiary area SBA is bent, the subsidiary area SBA may overlap with the main area MA in a thickness direction (e.g., the third direction DR3). The subsidiary area SBA may include pads connected to the display driver 200 and the circuit board 300. According to another embodiment, the subsidiary area SBA may be omitted, and the display driver 200 and the pads may be disposed in the non-display area NDA.

The display driver 200 may output signals and voltages for driving the display panel 100. The display driver 200 may supply data voltages to data lines. The display driver 200 may apply a supply voltage to a voltage line, and may supply gate control signals to the gate driver. The display driver 200 may be implemented as an integrated circuit (IC), and may be attached on the display panel 100 by a chip-on-glass (COG) technique, a chip-on-plastic (COP) technique, or ultrasonic bonding. For example, the display driver 200 may be disposed in the subsidiary area SBA, and may overlap with the main area MA in the thickness direction when the subsidiary area SBA is bent. As another example, the display driver 200 may be mounted on the circuit board 300.

The circuit board 300 may be attached onto the pads of the display panel 100 using an anisotropic conductive film (ACF). Lead lines of the circuit board 300 may be electrically connected to the pads of the display panel 300. The circuit board 300 may be a flexible printed circuit board (FPCB), a printed circuit board (PCB), or a flexible film such as a chip-on-film (COF).

The touch driver 400 may be mounted on the circuit board 300. The touch driver 400 may be connected to a touch sensing unit (e.g., a touch sensor or a touch sensing layer) of the display panel 100. The touch driver 400 may supply a touch driving signal to a plurality of touch electrodes of the touch sensing unit, and may sense a change in a capacitance between the plurality of touch electrodes. For example, the touch driving signal may be a pulse signal having a suitable frequency (e.g., a predetermined frequency). The touch driver 400 may determine whether or not there is an input (e.g., a touch event or a proximity input), and may determine the coordinates of the input based on an amount of the change in the capacitance between the touch electrodes. The touch driver 400 may be implemented as an integrated circuit (IC).

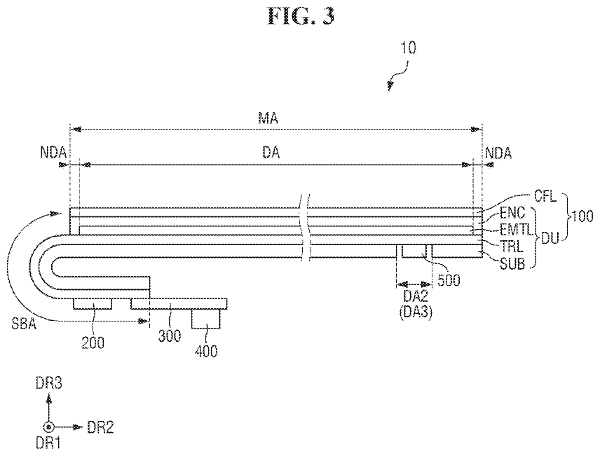

FIG. 3 is a cross-sectional view of the display device of FIG. 2 from the side.

Referring to FIG. 3, the display panel 100 may include a display layer DU and a color filter layer CFL. The display layer DU may include a substrate SUB, a transistor layer TRL, an emission material layer EMTL, and an encapsulation layer ENC.

The substrate SUB may be a base substrate or a base member. The substrate SUB may be a flexible substrate that may be bent, folded, or rolled. For example, the substrate SUB may include, but is not limited to, a polymer resin such as polyimide PI. According to another embodiment, the substrate SUB may include a glass material or a metal material.

The transistor layer TRL may be disposed on the substrate SUB. The transistor layer TRL may include a plurality of transistors forming pixel circuits of the pixels. The transistor layer TRL may include gate lines, data lines, voltage lines, gate control lines, fan-out lines for connecting the display driver 200 with the data lines, lead lines for connecting the display driver 200 with the pads, and the like. Each of the transistors may include a semiconductor region, a source electrode, a drain electrode, and a gate electrode. Further, for example, when the gate driver is formed on one side of the non-display area NDA of the display panel 100, the gate driver may also include transistors.

The transistor layer TRL may be disposed in the display area DA, the non-display area NDA, and the subsidiary area SBA. The transistors, the gate lines, the data lines, and the voltage lines in the thin-film transistor layer TRL for the pixels may be disposed in the display area DA. The gate control lines and the fan-out lines in the transistor layer TRL may be disposed in the non-display area NDA. The lead lines of the transistor layer TRL may be disposed in the subsidiary area SBA.

The emission material layer EMTL may be disposed on the transistor layer TRL. The emission material layer EMTL may include a plurality of light-emitting elements, each including a first electrode, a second electrode, and an emissive layer to emit light, and a pixel-defining layer for defining the pixels. The plurality of light-emitting elements in the emission material layer EMTL may be disposed in the display area DA.

According to an embodiment of the present disclosure, the emissive layer may be an organic emissive layer containing an organic material. The emissive layer may include a hole transporting layer, an organic light-emitting layer, and an electron transporting layer. When the first electrode receives a voltage and the second electrode receives a cathode voltage through the transistors of the transistor layer TRL, the holes and the electrons may move to the organic light-emitting layer through the hole transporting layer and the electron transporting layer, respectively, and may be combined with each other in the organic light-emitting layer to emit light.

According to another embodiment, the light-emitting elements may include quantum-dot light-emitting diodes, each including a quantum-dot emissive layer. According to another embodiment, the light-emitting elements may include inorganic light-emitting diodes, each including an inorganic semiconductor. According to another embodiment, the light-emitting elements may include micro light-emitting diodes.

The encapsulation layer ENC may cover the upper and side surfaces of the emission material layer EMTL, and may protect the emission material layer EMTL. The encapsulation layer ENC may include at least one inorganic layer, and at least one organic layer for encapsulating the emission material layer EMTL.

According to another embodiment, a touch layer (e.g., a touch sensing layer) may be further disposed on the encapsulation layer ENC. The touch layer may include a plurality of touch electrodes for sensing a user's touch by capacitive sensing, and touch lines connecting the plurality of touch electrodes with a touch driver. For example, the touch layer may sense a user's touch by mutual-capacitance sensing or self-capacitance sensing. According to another embodiment, the touch layer may be disposed on a separate substrate disposed on the display layer DU. In this case, the substrate supporting the touch layer may be a base member encapsulating the display layer DU.

The color filter layer CFL may be disposed on the encapsulation layer ENC. The color filter layer CFL may include a plurality of color filters associated with the plurality of emission areas, respectively. Each of the color filters may selectively transmit light of a desired wavelength (e.g., a particular or predetermined wavelength), and may block or absorb light of other wavelengths. The color filter layer CFL may absorb at least some of the light (e.g., external light) introduced from the outside of the display device 10 to reduce a reflection of the external light. Accordingly, the color filter layer CFL may prevent or substantially prevent distortion of colors due to the reflection of external light.

Because the color filter layer CFL is disposed directly on the encapsulation layer ENC, the display device 10 may not require a separate substrate for the color filter layer CFL. Therefore, the thickness of the display device 10 may be reduced (e.g., may be relatively smaller).

In some embodiments, the display device 10 may further include an optical device 500. The optical device 500 may be disposed in the second display area DA2 or the third display area DA3. The optical device 500 may emit or receive light in infrared, ultraviolet, and/or visible ranges. For example, the optical device 500 may be an optical sensor that senses light incident on the display device 10, such as a proximity sensor, an illuminance sensor, a camera sensor, and/or an image sensor.

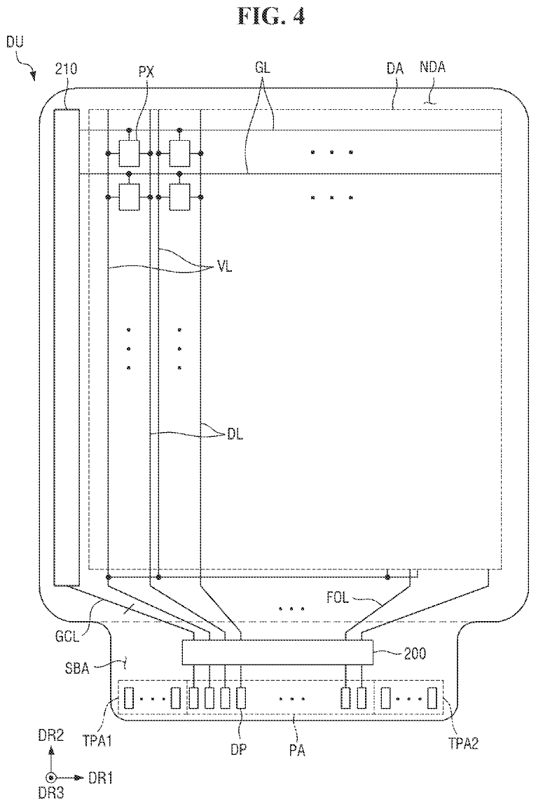

FIG. 4 is a plan view showing a display layer of a display device according to an embodiment of the present disclosure.

Referring to FIG. 4, the display layer DU may include a display area DA and a non-display area NDA.

The display area DA may be disposed at the center of the display device 10. In the display area DA, a plurality of pixels PX, a plurality of gate lines GL, a plurality of data lines DL, and a plurality of voltage lines VL may be disposed. Each of the plurality of pixels PX may be defined as a minimum unit that outputs light.

The plurality of gate lines GL may supply the gate signals received from the gate driver 210 to the plurality of pixels PX. The plurality of gate lines GL may be extended in the first direction DR1, and may be spaced apart from one another in the second direction DR2 crossing (e.g., intersecting) the first direction DR1.

The plurality of data lines DL may supply the data voltages received from the display driver 200 to the plurality of pixels PX. The plurality of data lines DL may be extended in the second direction DR2, and may be spaced apart from one another in the first direction DR1.

The plurality of voltage lines VL may supply the supply voltage received from the display driver 200 to the plurality of pixels PX. The supply voltage may be at least one of a driving voltage, an initialization voltage, a reference voltage, or a low-level voltage. The plurality of voltage lines VL may be extended in the second direction DR2, and may be spaced apart from one another in the first direction DR1.

The non-display area NDA may surround (e.g., around a periphery of) the display area DA. In the non-display area NDA, the gate driver 210, fan-out lines FOL, and gate control lines GCL may be disposed. The gate driver 210 may generate a plurality of gate signals based on the gate control signal, and may sequentially supply the plurality of gate signals to the plurality of gate lines GL in a suitable order (e.g., a predetermined order).

The fan-out lines FOL may be extended from the display driver 200 to the display area DA. The fan-out lines FOL may supply the data voltages received from the display driver 200 to the plurality of data lines DL.

The gate control line GCL may be extended from the display driver 200 to the gate driver 210. The gate control line GCL may supply the gate control signal received from the display driver 200 to the gate driver 210.

The subsidiary area SBA may include the display driver 200, a pad area PA, and first and second touch pad areas TPA1 and TPA2.

The display driver 200 may output signals and voltages for driving the display panel 100 to the fan-out lines FOL. The display driver 200 may supply data voltages to the data lines DL through the fan-out lines FOL. The data voltages may be applied to the plurality of pixels PX, so that a luminance of the plurality of pixels PX may be controlled. The display driver 200 may supply a gate control signal to the gate driver 210 through the gate control line GCL.

The pad area PA, the first touch pad area TPA1, and the second touch pad area TPA2 may be disposed at the edge of the subsidiary area SBA. The pad area PA, the first touch pad area TPA1, and the second touch pad area TPA2 may be electrically connected to the circuit board 300 (e.g., see FIG. 2) using a suitable material, such as an anisotropic conductive film and/or a self-assembly anisotropic conductive paste (SAP).

The pad area PA may include a plurality of display pads DP. The plurality of display pads DP may be connected to a graphic system through the circuit board 300. The plurality of display pads DP may be connected to the circuit board 300 to receive digital video data, and may supply the digital video data to the display driver 200.

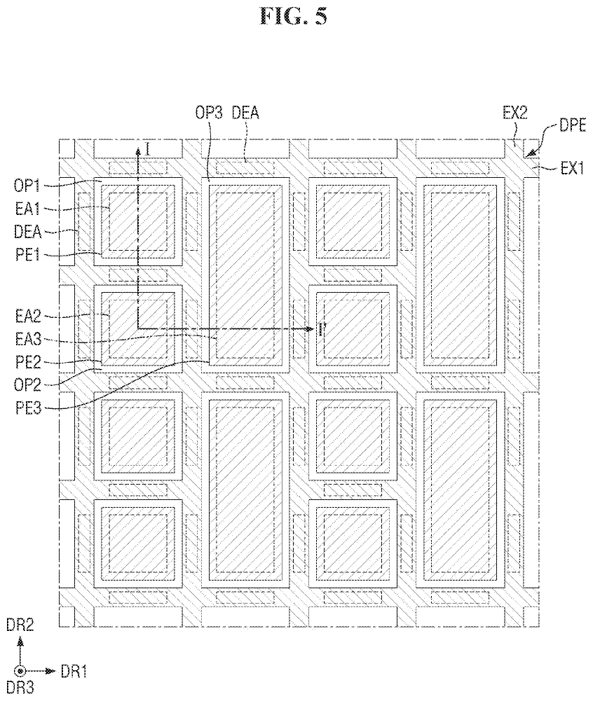

FIG. 5 is a plan view of pixel electrodes and a dummy pixel electrode of a display device according to an embodiment.

As shown in FIG. 5, the display device may include a first pixel electrode PE1, a second pixel electrode PE2, a third pixel electrode PE3, and a dummy pixel electrode DPE.

The first pixel electrode PE1, the second pixel electrode PE2, and the third pixel electrode PE3 may be disposed to be adjacent to one another. For example, the first pixel electrode PE1 and the second pixel electrode PE2 may be disposed to be adjacent to each other in the second direction DR2, the second pixel electrode PE2 and the third pixel electrode PE3 may be disposed to be adjacent to each other in the first direction DR1, and the third pixel electrode PE3 and the first pixel electrode PE1 may be disposed to be adjacent to each other in the first direction DR1.

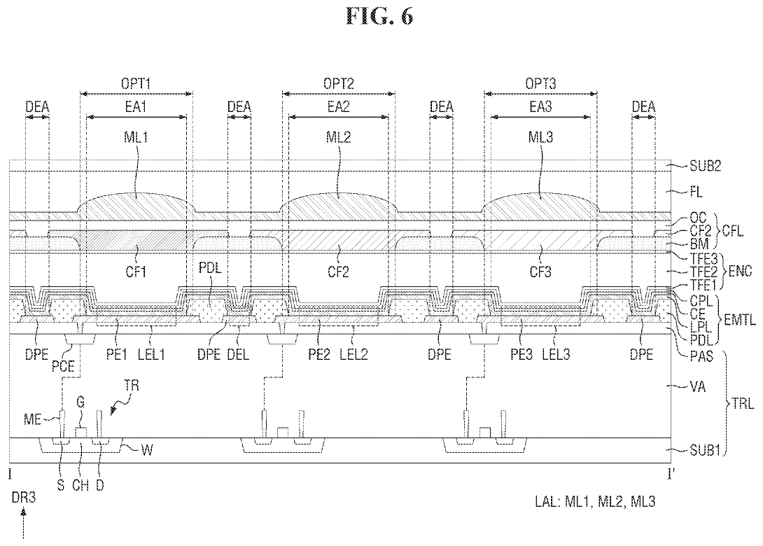

The dummy pixel electrode DPE may be disposed at (e.g., in or on) the same layer as that of the pixel electrodes. For example, the dummy pixel electrode DPE may be disposed at (e.g., in or on) the same layer as that of the first to third pixel electrodes PE1 to PE3. The dummy pixel electrode DPE and the pixel electrodes may include (e.g., may be made of) the same material. For example, the dummy pixel electrode DPE and the first to third pixel electrodes PE1 to PE3 may include (e.g., may be made of) the same material. For example, in a top-emission structure where light exits toward a common electrode (e.g., the common electrode CE of FIG. 6) with respect to an emissive layer (e.g., the layer LPL of FIG. 6), the pixel electrodes PE1 to PE3 and the dummy pixel electrode DPE may include (e.g., may be made up of) a single layer of molybdenum (Mo), titanium (Ti), copper (Cu), or aluminum (Al), or may have a stacked structure of aluminum and titanium (e.g., Ti/Al/Ti), a stacked structure of aluminum and ITO (e.g., ITO/Al/ITO), an APC alloy, or a stacked structure of the APC alloy and ITO (e.g., ITO/APC/ITO), in order to increase the reflectivity. The APC alloy is an alloy of silver (Ag), palladium (Pd), and copper (Cu).

The dummy pixel electrode DPE may be disposed, for example, between adjacent pixel electrodes. For example, the dummy pixel electrode DPE may be disposed between the first pixel electrode PE1 and the second pixel electrode PE2. In addition, the dummy pixel electrode DPE may be disposed between the second pixel electrode PE2 and the third pixel electrode PE3. In addition, the dummy pixel electrode DPE may be disposed between the third pixel electrode PE3 and the first pixel electrode PE1. When the dummy pixel electrode DPE is disposed between all the adjacent pixel electrodes, the dummy pixel electrode DPE may have a mesh shape that surrounds (e.g., around a periphery of) each of the first pixel electrode PE1, the second pixel electrode PE2, and the third pixel electrode PE3. In other words, the first pixel electrode PE1, the second pixel electrode PE2, and the third pixel electrode PE3 may be surrounded (e.g., around peripheries thereof) by the dummy pixel electrode DPE. For example, the first pixel electrode PE1, the second pixel electrode PE2, and the third pixel electrode PE3 may be surrounded by the dummy pixel electrode DPE when viewed from the top (e.g., in a plan view). In other words, the first pixel electrode PE1, the second pixel electrode PE2, and the third pixel electrode PE3 may be disposed in areas defined by the dummy pixel electrode DPE (hereinafter, referred to as open areas OP1, OP2, and OP3), respectively. For example, the first pixel electrode PE1 may be disposed in a first open area OP1 defined by the dummy pixel electrode DPE, the second pixel electrode PE2 may be disposed in a second open area OP2 defined by the dummy pixel electrode DPE, and the third pixel electrode PE3 may be disposed in a third open area OP3 defined by the dummy pixel electrode DPE.

The dummy pixel electrode DPE may include a plurality of first extended portions EX1 extending in the first direction DR1, and a plurality of second extended portions EX2 extending in the second direction DR2. The first extended portions EX1 may cross the second extended portions EX2. The first extended portions EX1 and the second extended portions EX2 may be connected at crossing points (e.g., intersections) of the first extended portions EX1 and the second extended portions EX2. The first extended portions EX1 and the second extended portions EX2 may be formed as a single piece (e.g., may be integrally formed). The first pixel electrode PE1, the second pixel electrode PE2, and the third pixel electrode PE3 may be disposed in the open areas OP1, OP2, and OP3, respectively, defined by being surrounded (e.g., around peripheries thereof) by the first extended portions EX1 and the second extended portions EX2.

A part of the first pixel electrode PE1 (e.g., an edge of the first pixel electrode PE1), a part of the second pixel electrode PE2 (e.g., an edge of the second pixel electrode PE2), a part of the third pixel electrode PE3 (e.g., an edge of the third pixel electrode PE3), and a part of the dummy pixel electrode DPE (e.g., an edge of the dummy pixel electrode DPE) may be covered by a bank PDL (e.g., see FIG. 6), which will be described in more detail below. In other words, a part of the first pixel electrode PE1 (e.g., an edge of the first pixel electrode PE1), a part of the second pixel electrode PE2 (e.g., an edge of the second pixel electrode PE2), a part of the third pixel electrode PE3 (e.g., an edge of the third pixel electrode PE3), and a part of the dummy pixel electrode DPE may partially overlap with the bank PDL. Portions of the first pixel electrode PE1, the second pixel electrode PE2, the third pixel electrode PE3, and the dummy pixel electrode DPE that are not covered by the bank PDL and are exposed may be defined as a first emission area EA1, a second emission area EA2, a third emission area EA3, and a dummy emission area DEA, respectively. For example, the first emission area EA1 may be an emission area of a first pixel including the first pixel electrode PE1, the second emission area EA2 may be an emission area of a second pixel including the second pixel electrode PE2, the third emission area EA3 may be an emission area of a third pixel including the third pixel electrode PE3, and the dummy emission area DEA may be a dummy emission area DEA of a dummy pixel including the dummy pixel electrode DPE.

For example, as shown in FIG. 5, the dummy emission area DEA may be disposed on at least one of an upper side, a lower side, a left side, or a right side of each of the pixel electrodes. For example, the dummy emission area DEA may be disposed on each of the upper, lower, left, and right sides of the first pixel electrode PE1.

FIG. 6 is a cross-sectional view taken along the line I-I′ of FIG. 5.

Referring to FIG. 6, the display device 10 may include a transistor layer TRL, an emission material layer EMTL, an encapsulation layer ENC, a color filter layer CFL, a lens array layer LAL, and an encapsulation substrate SUB2.

The base substrate SUB1 may be a silicon substrate, a germanium substrate, or a silicon-germanium substrate. The base substrate SUB1 may be a substrate doped with first-type impurities.

A well W may be formed at (e.g., in or on) the base substrate SUB1 (e.g., inside the base substrate SUB1). The well W may be doped with second-type impurities. The second-type impurities may be different from the first-type impurities. For example, when the first-type impurities are p-type impurities, the second-type impurities may be n-type impurities. On the other hand, when the first-type impurities are n-type impurities, the second-type impurities may be p-type impurities.

A source region S, a drain region D, and a channel region CH of a transistor TR may be located in the well W. For example, the source region S (or source electrode) and the drain region D (or drain electrode) of the transistor TR may be located in the well W. Each of the source region S and the drain region D may be doped with the first-type impurities. The gate electrode G of the transistor TR may cross and overlap with the well W. When viewed from the top (e.g., in a plan view), the well W crossing the gate electrode G may be defined as two regions. One of the two regions may be the source region S and the other may be the drain region D. In other words, in the well W, the source region S and the drain region D may be located on opposite sides of the gate electrode G, respectively, with the gate electrode G therebetween. The channel region CH of the transistor TR may be located where the gate electrode G overlaps with the well W.

The source region S may include a first low-concentration impurity region having a lower impurity concentration than that of the other portions of the source region S. In other words, a portion of the source region S may include impurities at a lower concentration than that of the other portions of the source region S. The drain region D may include a second low-concentration impurity region having a lower impurity concentration than that of the other portions of the drain region D. In other words, a portion of the drain region D may include impurities at a lower concentration than that of the other portions of the drain region D.

The first low-concentration impurity region and the second low-concentration impurity region may be disposed to be closer to the channel region CH of the transistor TR. For example, the first low-concentration impurity region may be disposed closer to the channel region CH, such that it overlaps with a first spacer disposed on one side of the gate electrode G. The second low-concentration impurity region may be disposed closer to the channel region CH, such that it overlaps with a second spacer disposed on the opposite side of the gate electrode G. As described above, the distance between a high-concentration impurity region of the source region S and a high-concentration impurity region of the drain region D may be increased due to the first low-concentration impurity region and the second low-concentration impurity region. As a result, the length of the channel region CH may be increased. Accordingly, it may be possible to prevent or substantially prevent short channel effects, such as punch-through and hot carrier.

An interlayer dielectric film VA may be disposed on the base substrate SUB1.

A passivation film PAS may be disposed on the interlayer dielectric film VA.

The emission material layer EMTL may be disposed on the passivation film PAS. The emission material layer EMTL may include, for example, a first light-emitting element LEL1, a second light-emitting element LEL2, a third light-emitting element LEL3, and a dummy light-emitting element DEL disposed in different emission areas from each other. For example, the first light-emitting element LEL1 of the emission material layer EMTL may be disposed in the first emission area EA1, the second light-emitting element LEL2 of the emission material layer EMTL may be disposed in the second emission area EA2, the third light-emitting element LEL3 of the emission material layer EMTL may be disposed in the third emission area EA3, and the dummy light-emitting element DEL of the emission material layer EMTL may be disposed in the dummy emission area DEA.

Each of the first light-emitting element LEL1, the second light-emitting element LEL2, the third light-emitting element LEL3, and the dummy light-emitting element DEL may emit white light.

The first light-emitting element LEL1 may include a first pixel electrode PE1 (e.g., a first anode electrode), a light-providing layer LPL, and a common electrode CE stacked on one another in the third direction DR3.

The second light-emitting element LEL2 may include a second pixel electrode PE2 (e.g., a second anode electrode), the light-providing layer LPL, and the common electrode CE stacked on one another in the third direction DR3.

The third light-emitting element LEL3 may include a third pixel electrode PE3 (e.g., a third anode electrode), the light-providing layer LPL, and the common electrode CE stacked on one another in the third direction DR3.

The dummy light-emitting element DEL may include a dummy pixel electrode DPE (e.g., a dummy anode electrode), the light-providing layer LPL, and the common electrode CE.

The light-providing layer LPL and the common electrode CE may be common layers commonly used for the light-emitting elements LEL1 to LEL3 and the dummy light-emitting element DEL. In other words, the plurality of light-emitting elements LEL1 to LEL3 and the dummy light-emitting elements DEL of the emission material layer EMTL may share the light-providing layer LPL and the common electrode CE.

The light-providing layer LPL may include a plurality of emissive layers for providing light of different colors. The plurality of emissive layers may be stacked on one another in the third direction DR3. Different colored light from the emissive layers may be mixed with each other to generate white light. The light-providing layer LPL may further include a charge generating layer.

Each of the first pixel electrode PE1, the second pixel electrode PE2, and the third pixel electrode PE3 may be connected to the source region S of a corresponding transistor TR through a pixel connection electrode PCE and a metal connection layer ME.

The dummy pixel electrode DPE may receive power from the outside. For example, an edge of the dummy pixel electrode DPE may be extended in at least one of the first or second directions DR1 or DR2, and may be connected to a power supply unit (e.g., a power supply). The power supply unit may supply dummy power (e.g., a DC voltage or a DC current) to the dummy pixel electrode DPE. The dummy power may be smaller than a voltage applied to a pixel electrode (hereinafter, referred to as pixel voltage). For example, when the dummy power is a DC voltage, the DC voltage may be smaller than the pixel voltage of the lowest grayscale level applied to the pixel electrode. Accordingly, the power consumption by the DC dummy power applied to the dummy pixel electrode DPE may be reduced.

The first pixel electrode PE1 may be disposed in line with the first emission area EA1, the second pixel electrode PE2 may be disposed in line with the second emission area EA2, the third pixel electrode PE3 may be disposed in line with the third emission area EA3, and the dummy pixel electrode DPE may be disposed in line with the dummy emission area DEA.

The bank PDL (e.g., a pixel-defining film) may be disposed on the first pixel electrode PE1, the second pixel electrode PE2, the third pixel electrode PE3, and the dummy pixel electrode DPE.

The bank PDL may define the emission area of each pixel (e.g., the first emission area EA1 of the first pixel, the second emission area EA2 of the second pixel, and the third emission area EA3 of the third pixel). As such, the bank PDL may be disposed to expose some regions of the first pixel electrode PE1, the second pixel electrode PE2, the third pixel electrode PE3, and the dummy pixel electrode DPE on the passivation film PAS, for example. The bank PDL may cover edges of the first pixel electrode PE1, the second pixel electrode PE2, the third pixel electrode PE3, and the dummy pixel electrode DPE. The bank PDL may be formed of an organic layer, such as an acryl resin, an epoxy resin, a phenolic resin, a polyamide resin, and/or a polyimide resin.

The light-providing layer LPL may be disposed on the pixel electrodes PE1, PE2 and PE3, the dummy pixel electrode DPE, and the bank PDL. For example, the light-providing layer LPL may be disposed on the first pixel electrode PE1, the second pixel electrode PE2, the third pixel electrode PE3, the dummy pixel electrode DPE, and the bank PDL.

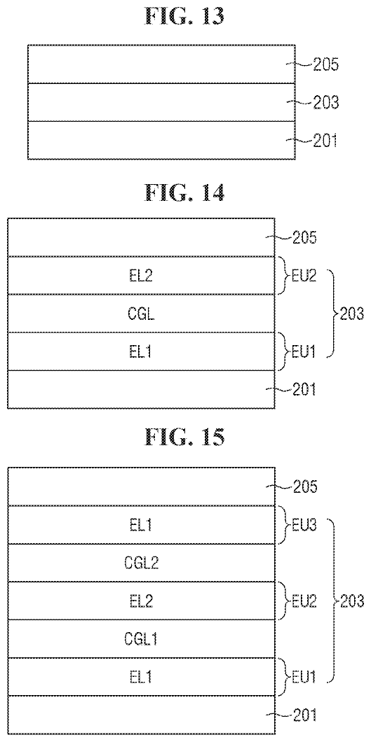

The light-providing layer LPL may include a plurality of light-emitting units (e.g., see FIGS. 13 to 19). For example, the light-providing layer LPL may include a first light-emitting unit (e.g., a first light-emitting layer), a second light-emitting unit (e.g., a second light-emitting layer), and a third light-emitting unit (e.g., a third light-emitting layer) stacked on one another in the third direction DR3. Each of the light-emitting units may provide light of different wavelengths. For example, the first light-emitting unit, the second light-emitting unit, and the third light-emitting unit may emit light of different colors from each other. For example, the light-providing layer LPL may have a tandem structure in which a plurality of light-emitting units for providing light of different colors from each other are stacked on one another in the vertical direction (e.g., in the third direction DR3).

The first light-emitting unit may be disposed on the pixel electrodes PE1, PE2, and PE3 and the dummy pixel electrode DPE. The first light-emitting unit may include a first emissive layer, a hole transporting layer, an organic material layer, and an electron transporting layer.

The second light-emitting unit may be disposed on the first light-emitting unit.

The second light-emitting unit may include a second emissive layer, a hole transporting layer, an organic material layer, and an electron transporting layer.

The third light-emitting unit may be disposed on the second light-emitting unit. The third light-emitting unit may include a third emissive layer, a hole transporting layer, an organic material layer, and an electron transporting layer.

The light-emitting elements LEL1, LEL2, and LEL3 and the dummy light-emitting element DEL may mix light of a first color (e.g., blue) from the first light-emitting unit, light of a second color (e.g., red) from the second light-emitting unit, and light of a third color (e.g., green) from the third light-emitting unit to provide white light. For example, each of the first light-emitting element LEL1, the second light-emitting element LEL2, the third light-emitting element LEL3, and the dummy light-emitting element DEL may emit white light.

In addition, the light-providing layer LPL may further include at least one charge generating layer. The charge generating layer may be disposed between adjacent light-emitting units in the third direction DR3, for example. The charge generating layer may include, for example, a first charge generating layer and a second charge generating layer stacked on one another in the third direction. In this case, the first charge generating layer may be disposed between the first light-emitting unit and the second light-emitting unit, and the second charge generating layer may be disposed between the second light-emitting unit and the third light-emitting unit.

Each charge generating layer may include a negative-charge generating layer and a positive-charge generating layer. For example, the first charge generating layer may include a first negative-charge generating layer and a first positive-charge generating layer stacked in the third direction DR3, and the second charge generating layer may include a second negative-charge generating layer and a second positive-charge generating layer stacked in the third direction DR3.

The common electrode CE may be disposed on the light-providing layer LPL. For example, the common electrode CE may be disposed on the light-providing layer LPL to overlap with the first pixel electrode PE1, the second pixel electrode PE2, the third pixel electrode PE3, the dummy pixel electrode DPE, the first emission area EA1, the second emission area EA2, the third emission area EA3, and the dummy emission area DEA. In the top-emission structure, the common electrode CE may be formed of a transparent conductive material (TCP), such as ITO and IZO, that may transmit light, or a semi-transmissive conductive material, such as magnesium (Mg), silver (Ag), and/or an alloy of magnesium (Mg) and silver (Ag). When the common electrode CM is formed of a semi-transmissive metal material, the light extraction efficiency may be increased by using microcavities.

A capping layer CPL may be disposed on the common electrode CE. The capping layer CPL may include an inorganic insulating material. In an embodiment, the capping layer CPL may include aluminum oxide, titanium oxide, tantalum oxide, hafnium oxide, zinc oxide, silicon oxide, silicon nitride, and/or silicon oxynitride.

The encapsulation layer ENC may be disposed on the capping layer CPL. The encapsulation layer ENC may cover the upper and side surfaces of the emission material layer EMTL, and may protect the emission material layer EMTL. The encapsulation layer ENC may include at least one inorganic layer and at least one organic layer for encapsulating the emission material layer EMTL. The encapsulation layer ENC may include one or more inorganic films TFE1 and TFE3 to prevent or substantially prevent permeation of oxygen and/or moisture into the emission material layer EMTL. In addition, the encapsulation layer ENC may include at least one organic film to protect the emission material layer EMTL from particles, such as dust. For example, the encapsulation layer ENC may include a first inorganic encapsulation film TFE1, an organic encapsulation film TFE2, and a second inorganic encapsulation film TFE3.

The first inorganic encapsulation film TFE1 may be disposed on the capping layer CPL. The organic encapsulation film TFE2 may be disposed on the first inorganic encapsulation film TFE1. The second inorganic encapsulation film TFE3 may be disposed on the organic encapsulation film TFE2. The first inorganic encapsulation film TFE1 and the second inorganic encapsulation film TFE3 may include (e.g., may be made up of) multiple layers, in which one or more inorganic layers from among a silicon nitride layer, a silicon oxynitride layer, a silicon oxide layer, a titanium oxide layer, and an aluminum oxide layer are alternately stacked on one another. The organic encapsulation film TFE2 may be an organic film, such as an acryl resin, an epoxy resin, a phenolic resin, a polyamide resin, a polyimide resin, and/or the like.

A light-blocking layer BM may be disposed on the encapsulation layer ENC. The light-blocking layer BM may include a plurality of holes OPT1, OPT2, and OPT3 overlapping with the emission areas EA1, EA2, and EA3, respectively. For example, the first hole OPT1 may overlap with the first emission area EA1. The second hole OPT2 may overlap with the second emission area EA2. The third hole OPT3 may overlap with the third emission area EA3. The area or size of the holes OPT1, OPT2, and OPT3 may be larger than that of the corresponding emission areas EA1, EA2, and EA3 defined by the bank PDL. As the holes OPT1, OPT2, and OPT3 of the light-blocking layer BM are formed to be larger than the emission areas EA1, EA2, and EA3, the light exiting from the emission areas EA1, EA2, and EA3 may be seen by a user from the front as well as from the sides.

The light-blocking layer BM may include a light-absorbing material. For example, the light-blocking layer BM may include an inorganic black pigment or an organic black pigment. The inorganic black pigment may include, but is not limited to, carbon black, and the organic black pigment may include, but is not limited to, at least one of lactam black, perylene black, or aniline black. The light-blocking layer BM may prevent or substantially prevent visible light from penetrating and mixing colors between the first to third emission areas EA1, EA2, and EA3 to improve the color gamut of the display device 10.

The display device 10 may include a plurality of color filters CF1, CF2, and CF3 disposed on the emission areas EA1, EA2, and EA3. The color filters CF1, CF2, and CF3 may be associated with the emission areas EA1, EA2, and EA3, respectively. For example, the color filters CF1, CF2, and CF3 may be disposed on the light-blocking layer BM including the plurality of holes OPT1, OPT2, and OPT3 associated with the emission areas EA1, EA2, and EA3, respectively.

The color filters CF1, CF2, and CF3 include a first color filter CF1, a second color filter CF2, and a third color filter CF3 associated with the different emission areas EA1, EA2, and EA3, respectively. The color filters CF1, CF2, and CF3 may include a colorant, such as a dye, and a pigment that absorbs light in various wavelength ranges other than light in a desired wavelength range (e.g., a particular or predetermined wavelength range), and may be disposed in association with the light exiting from the emission areas EA1, EA2, and EA3. For example, the first color filter CF1 may be a red color filter that is disposed to overlap with the first emission area EA1, and may transmit only red first light. The second color filter CF2 may be a green color filter that is disposed to overlap with the second emission area EA2, and may transmit only green second light. The third color filter CF3 may be a blue color filter that is disposed to overlap with the third emission area EA3, and may transmit only blue third light.

The color filters CF1, CF2, and CF3 may be spaced apart from one another on the light-blocking layer BM. The color filters CF1, CF2, and CF3 may cover the holes OPT1, OPT2, and OPT3 of the light-blocking layer BM, and may have an area that is larger than the holes, such that they are spaced apart from one another on the light-blocking layer BM. However, the present disclosure is not limited thereto. The color filters CF1, CF2, and CF3 may partially overlap with one another. The different color filters CF1, CF2, and CF3 may not overlap with the emission areas EA1, EA2, and EA3, and may overlap with one another on the light-blocking layer BM. In the display device 10, because the color filters CF1, CF2, and CF3 overlap with one another, the intensity of reflected light caused by external light may be reduced. Furthermore, the colors of reflected light by external light may be controlled by adjusting the arrangement, shape, and area of the color filters CF1, CF2, and CF3 when viewed from the top (e.g., in a plan view).

An overcoat layer OC may be disposed on the color filters CF1, CF2, and CF3 to provide upper ends of the color filters CF1, CF2, and CF3. The overcoat layer OC may be a colorless light-transmitting layer having no color in the visible light band. For example, the overcoat layer OC may include a colorless light-transmitting organic material, such as an acryl-based resin.

The lens array layer LAL may be disposed on the overcoat layer OC. The lens array layer LAL may include a plurality of micro lenses ML1, ML2, and ML3. For example, the lens array layer LAL may include a first micro lens ML1 disposed in line with the first emission area EA1 or the first hole OPT1, a second micro lens ML2 disposed in line with the second emission area EA2 or the second hole OPT2, and a third micro lens ML3 disposed in line with the third emission area EA3 or the third hole OPT3.

Each of the micro lenses ML1, ML2, and ML3 may have a larger size than the corresponding hole OPT1, OPT2, and OPT3. For example, the micro lenses ML1, ML2, and ML3 may completely cover the holes OPT1, OPT2, and OPT3, respectively, and may overlap with portions of the light-blocking layer BM. Because the micro lenses ML1, ML2, and ML3 may be formed to be larger than the holes OPT1, OPT2, and OPT3 of the light-blocking layer BM, the light exiting from the emission areas EA1, EA2, and EA3 may be seen by a user from the front, as well as from the sides.

A filler FL may be disposed on the lens array layer LAL. The filler FL may be disposed between adjacent micro lenses.

The encapsulation substrate SUB2 may be disposed on the filler FL.

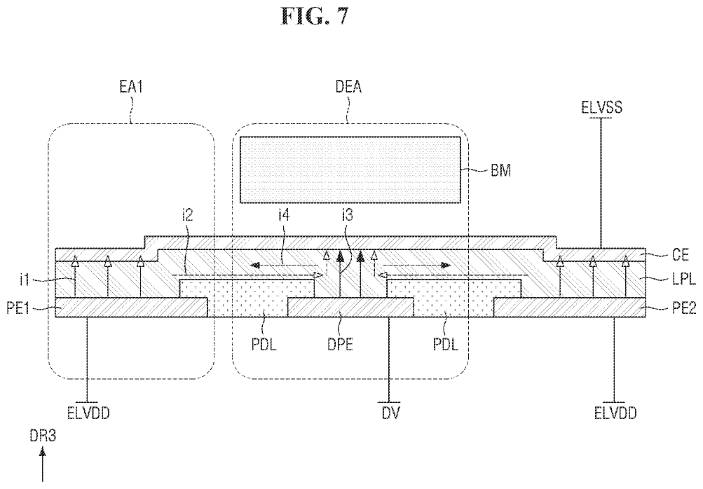

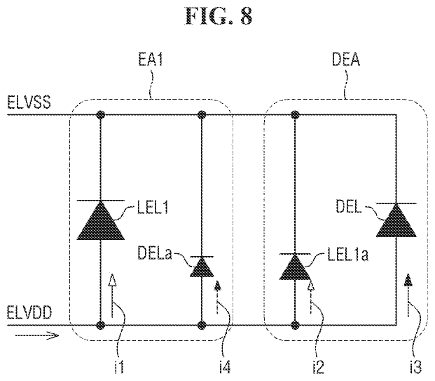

FIG. 7 is a view illustrating current flows in an emission area and a dummy emission area in a display device according to an embodiment. FIG. 8 is an equivalent circuit diagram in the emission area and the dummy emission area of FIG. 7.

Referring to FIGS. 7 and 8, a first current i1 in an emission area (e.g., the first emission area EA1) may be generated by an electric field between a pixel electrode (e.g., the first pixel electrode PE1) and the common electrode CE. For example, the first current i1 may be generated by an electric field based on a voltage difference between a pixel voltage (e.g., a pixel voltage having a driving voltage level) applied to the first pixel electrode PE1 and a common voltage applied to the common electrode CE.

The first current i1 may be, for example, a main current generated from the first light-emitting element LEL1. The first current i1 may flow from the first pixel electrode PE1 toward the common electrode CE in the third direction DR3.

A second current i2 may be, for example, a current (e.g., a lateral leakage current) that branches off from the first current i1, and flows in the first direction DR1 or the second direction DR2. The second current i2 may be smaller than the first current i1. The second current i2 may travel, for example, toward the adjacent dummy emission area DEA along the light-providing layer LPL.

As shown in FIGS. 7 and 8, a third current i3 in the dummy emission area DEA may be generated by an electric field between the dummy pixel electrode DPE and the common electrode CE. For example, the third current i3 may be generated by an electric field based on a voltage difference between a dummy power (e.g., a dummy voltage DV) applied to the dummy pixel electrode DPE and the common voltage applied to the common electrode CE. For example, the dummy voltage DV may be greater than a common voltage ELVSS, and less than a driving voltage ELVDD. In more detail, the dummy voltage DV may be smaller than the common voltage ELVSS and the pixel voltage of the lowest grayscale level.

The third current i3 may be, for example, a main current generated from the dummy light-emitting element DEL. The third current i3 may flow from the dummy pixel electrode DPE toward the common electrode CE along the third direction DR3.

A fourth current i4 may be, for example, a current (e.g., a side leakage current) that branches off from the third current i3, and flows in the first direction DR1 or the second direction DR2. The fourth current i4 may be smaller than the third current i3. The fourth current i4 may travel to adjacent emission areas (e.g., the first emission area EA1 and the second emission area EA2) along the light-providing layer LPL, for example.

The second current i2, which is a relatively large leakage current, may be consumed through, for example, the dummy emission area DEA. Accordingly, because most of the second current i2 generated in the first emission area EA1 may be consumed in the dummy emission area DEA, the second current i2 may not flow to the second emission area EA2. Accordingly, it may be possible to prevent or substantially prevent adjacent light-emitting elements from emitting light due to a lateral leakage current.

Incidentally, the dummy light-emitting element of the dummy emission area DEA may emit light by the third current i3 and the second current i2, but the dummy emission area DEA is covered by the light-blocking layer BM, and thus, light from the dummy emission area DEA may not be involved in representing images.

The first to fourth currents i1 to i4 may have descending magnitudes in the order of the first current i1, the third current i3, the second current i2, and the fourth current i4 (e.g., i1>i3>i2>i4). For example, the first current i1 may be the largest and the fourth current i4 may be the smallest.

In FIG. 8, a leakage light-emitting element LEL1a emits light by the second current i2 branching off from the first current i1 generated from the first light-emitting element LEL1, and a leakage dummy light-emitting element DELa emits light by the fourth current i4 branching off from the third current i3 generated from the dummy light-emitting element DEL.

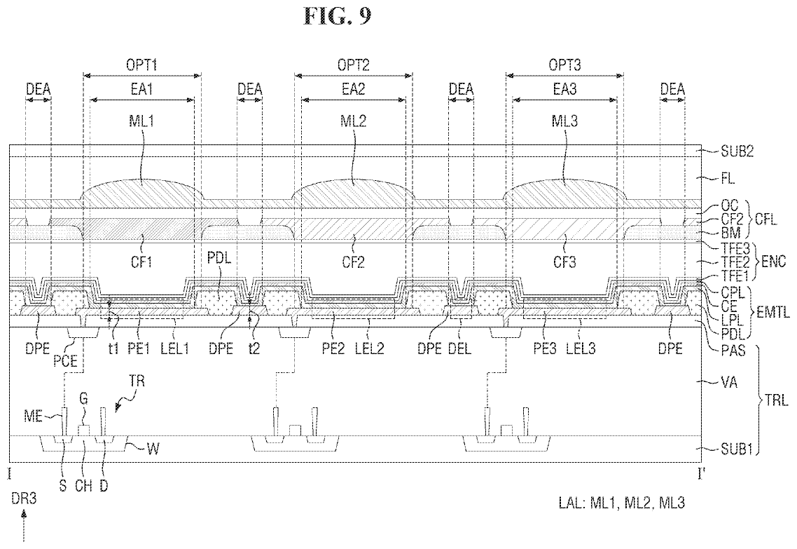

FIG. 9 is a cross-sectional view taken along the line I-I′ of FIG. 5.

A display device illustrated in FIG. 9 may be different from the display device 10 of FIG. 6, in that pixel electrodes and a dummy pixel electrode in FIG. 9 have different thicknesses. Redundant description of the elements illustrated in FIG. 9 that are the same or substantially the same as those described above may not be repeated, and the differences in FIG. 9 may be mainly described in more detail hereinafter.

Referring to FIG. 9, the dummy pixel electrode DPE may have a thickness t2 greater than the thicknesses t1 (e.g., t2>t1) of the pixel electrodes (e.g., the first pixel electrode PE1). For example, the thickness t2 of the dummy pixel electrode DPE may be greater than the thickness t1 of the first pixel electrode PE1. Similarly, the thickness t2 of the dummy pixel electrode DPE may be greater than the thickness of the second pixel electrode PE2. In addition, the thickness t2 of the dummy pixel electrode DPE may be greater than the thickness of the third pixel electrode PE3. Accordingly, the distance between the dummy pixel electrode DPE and the common electrode CE may be shorter than the distance between the pixel electrodes and the common electrode CE. Accordingly, a sufficiently strong electric field may be generated between the dummy pixel electrode DPE and the common electrode CE, even with a smaller dummy power. In other words, the dummy light-emitting element DEL may be driven even with a smaller dummy power. Accordingly, it may be possible to reduce power consumption for driving the dummy light-emitting element DEL.

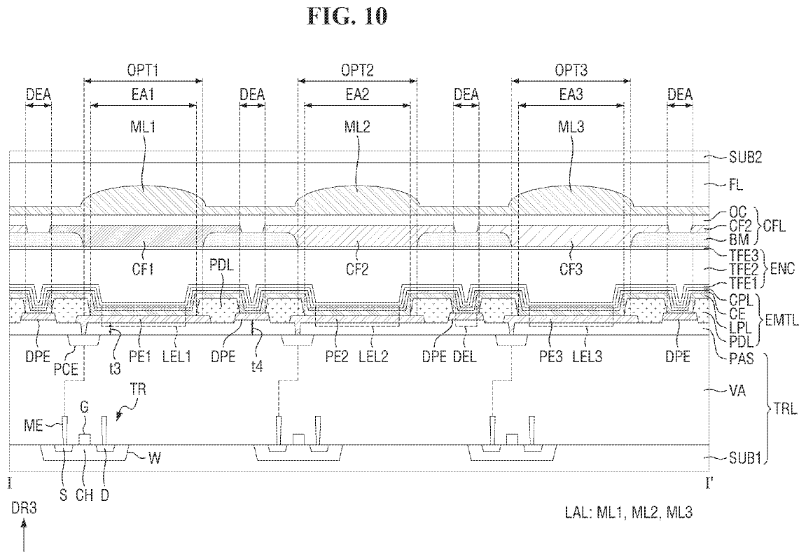

FIG. 10 is a cross-sectional view taken along the line I-I′ of FIG. 5.

A display device of FIG. 10 may be different from the display device 10 of FIG. 6, in that in FIG. 10, the thickness of a passivation film PAS in emission areas is different from the thickness of the passivation film PAS in a dummy emission area DEA. Redundant description of the elements illustrated in FIG. 10 that are the same or substantially the same as those described above may not be repeated, and the differences of FIG. 10 may be mainly described in more detail hereinafter.

As shown in FIG. 10, the passivation film PAS may have a larger thickness in the dummy emission area DEA than that in the emission areas EA1, EA2, and EA3. For example, the thickness t4 of the passivation film PAS in the dummy emission area DEA may be greater than the thickness t3 of the passivation film PAS in the first emission area EA1. Similarly, the thickness t4 of the passivation film PAS in the dummy emission area DEA may be greater than the thickness of the passivation film PAS in the second emission area EA2. In addition, the thickness t4 of the passivation film PAS in the dummy emission area DEA may be greater than the thickness of the passivation film PAS in the third emission area EA3. As such, the dummy pixel electrode DPE in the dummy emission area DEA may be higher in the third direction DR3 than the pixel electrodes PE1, PE2 and PE3 in the emission areas. Accordingly, the distance between the dummy pixel electrode DPE and the common electrode CE may be shorter than the distance between the pixel electrodes PE1, PE2 and PE3 and the common electrode CE. Accordingly, a sufficiently strong electric field may be generated between the dummy pixel electrode DPE and the common electrode CE, even with a smaller dummy power. In other words, the dummy light-emitting element DEL may be driven even with a smaller dummy power. Accordingly, it may be possible to reduce power consumption for driving the dummy light-emitting element DEL.

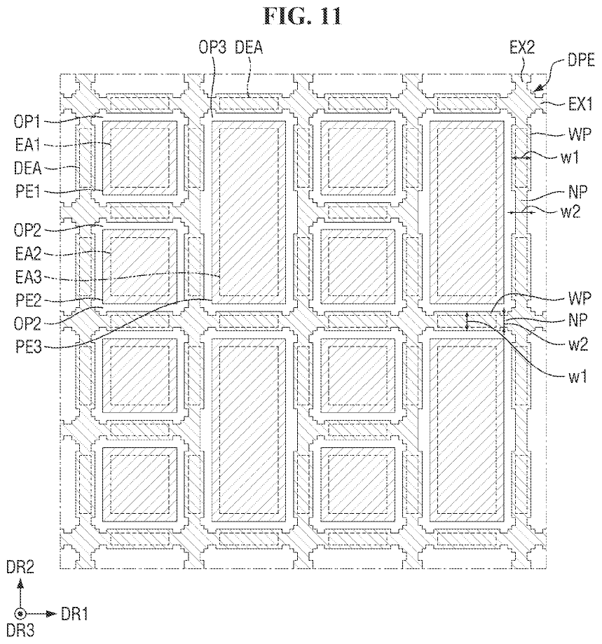

FIG. 11 is a plan view of pixel electrodes and a dummy pixel electrode of a display device according to an embodiment.

A display device of FIG. 11 may be different from the display device 10 of FIG. 5, in that a dummy pixel electrode DPE of FIG. 11 has at least two different widths. Redundant description of the elements illustrated in FIG. 11 that are the same or substantially the same as those described above may not be repeated, and the differences of FIG. 11 may be mainly described in more detail hereinafter.

Referring to FIG. 11, at least a portion of the dummy pixel electrode DPE may have a different width than other portions thereof. For example, a line width w2 of at least a portion of the dummy pixel electrode DPE may be smaller than line widths w1 of the other portions of the dummy pixel electrode DPE (e.g., w2<w1). The portion of the dummy pixel electrode DPE that has a relatively larger width is defined as a wide portion WP of the dummy pixel electrode DPE. The portion of the dummy pixel electrode DPE that has a relatively smaller width is defined as a narrow portion NP of the dummy pixel electrode DPE. The width w2 of the narrow portion NP may be smaller than the width w1 of the wide portion WP. The width w1 or w2 may refer to, for example, sizes in the first direction DR1 or the second direction DR2. For example, when the narrow portion NP is formed at a first extended portion EX1 of the dummy pixel electrode DPE, the width w1 of the wide portion WP and the width w2 of the narrow portion NP of that first extended portion EX1 may refer to the sizes in the second direction DR2. On the other hand, when the narrow portion NP is formed at a second extended portion EX2 of the dummy pixel electrode DPE, the width w1 of the wide portion WP and the width w2 of the narrow portion NP of that second extended portion EX2 may refer to the sizes in the first direction DR1.

The wide portion WP of the dummy pixel electrode DPE may be disposed in line with, for example, the dummy emission area DEA defined by the bank PDL. In other words, the wide portion WP of the dummy pixel electrode DPE may overlap with the dummy emission area DEA.

The narrow portion NP of the dummy pixel electrode DPE may be disposed in line with, for example, other portions than the dummy emission area DEA defined by the bank PDL. In other words, the narrow portion NP of the dummy pixel electrode DPE may not overlap with the dummy emission area DEA.

Because the dummy pixel electrode DPE has the narrow portion NP, the distance between the pixel electrode and the dummy pixel electrode DPE may be increased at the narrow portion NP. For example, the distance between the first pixel electrode PE1 and the dummy pixel electrode DPE at the narrow portion NP may be greater than the distance between the first pixel electrode PE1 and the dummy pixel electrode DPE at the wide portion WP. Accordingly, a horizontal electric field between the dummy pixel electrode DPE and the pixel electrodes PE1, PE2, and PE3 may be reduced, thereby, suppressing voltage fluctuations of the pixel electrodes PE1, PE2, and PE3. Accordingly, it may be possible to prevent or substantially prevent deterioration of image quality.

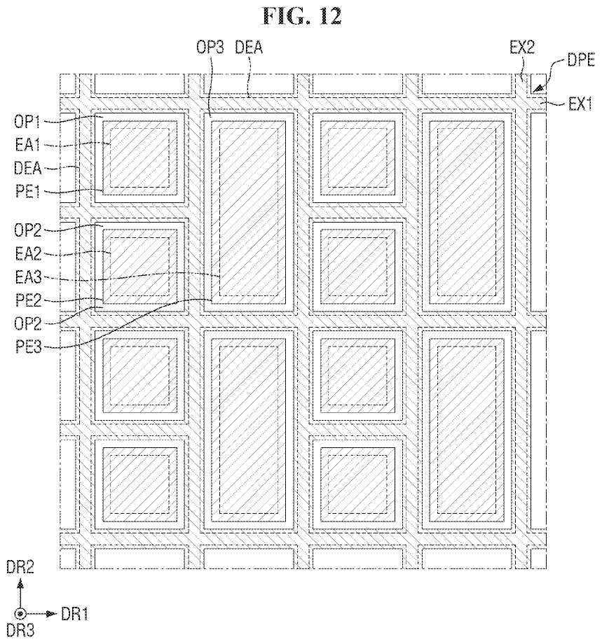

FIG. 12 is a plan view of pixel electrodes and a dummy pixel electrode DPE of a display device according to an embodiment.

A display device of FIG. 12 may be different from the display device 10 of FIG. 5, in that in FIG. 12, a dummy emission area DEA has the same or substantially the same shape as that of a dummy pixel electrode DPE. Redundant description of the elements illustrated in FIG. 12 that are the same or substantially the same as those described above may not be repeated, and the differences of FIG. 12 may be mainly described in more detail hereinafter.

Referring to FIG. 12, the dummy emission area DEA may have the same or substantially the same shape as that of the dummy pixel electrode DPE. For example, the dummy emission area DEA may have a mesh pattern. In other words, the dummy emission area DEA may be extended along the first extended portions EX1 and the second extended portions EX2 of the dummy pixel electrode DPE. The dummy emission area DEA may have a shape surrounding (e.g., around a periphery of) each of the pixel electrodes PE1, PE2, and PE3. For example, the dummy emission area DEA may have a mesh pattern surrounding (e.g., around a periphery of) each of the first pixel electrode PE1, the second pixel electrode PE2, and the third pixel electrode PE3.

The dummy emission area DEA of FIG. 12 may be covered by the above-described light-blocking layer BM.

Various structures of the light-emitting elements (e.g., the light-emitting elements LEL1, LEL2, and LEL3 of FIG. 6) will be described in more detail hereinafter with reference to FIGS. 13 through 19.

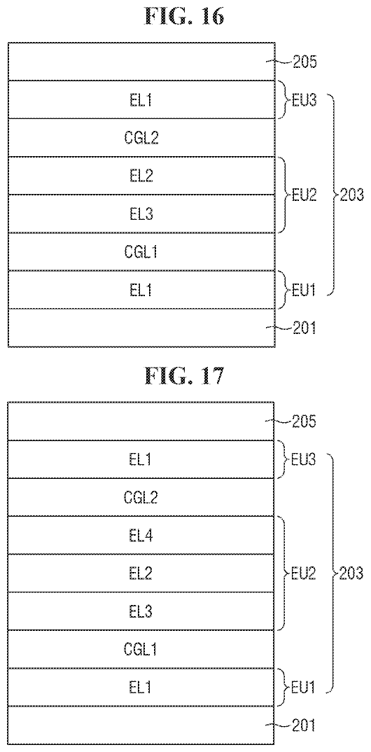

FIG. 13 is a cross-sectional view showing a structure of a display element according to an embodiment of the present disclosure. FIGS. 14 through 17 are cross-sectional views illustrating structures of light-emitting elements according to embodiments.

Referring to FIG. 13, a light-emitting element (e.g., an organic light-emitting diode) according to an embodiment may include a pixel electrode 201, a common electrode 205, and a light-providing layer 203 between the pixel electrode 201 and the common electrode 205. The pixel electrode 201 may be one of the first pixel electrode PE1, the second pixel electrode PE2, the third pixel electrode PE3, or the dummy pixel electrode DPE described above. In addition, the common electrode 205 may be the above-described common electrode CE. The light-providing layer 203 may be the above-described light-providing layer LPL.

The pixel electrode 201 may include a transparent conductive oxide, such as indium tin oxide (ITO), indium zinc oxide (IZO), zinc oxide (ZnO), indium oxide (In₂O₃), indium gallium oxide (IGO), and/or aluminum zinc oxide (AZO). The pixel electrode 201 may include a reflective layer containing silver (Ag), magnesium (Mg), aluminum (Al), platinum (Pt), palladium (Pd), gold (Au), nickel (Ni), neodymium (Nd), iridium (Ir), chrome (Cr), or a suitable compound thereof. For example, the pixel electrode 201 may have a three-layered structure of ITO/Ag/ITO.

The common electrode 205 may be disposed on the light-providing layer 203. The common electrode 205 may include a material having a low work function, an alloy, an electrically conductive compound, or any suitable combination thereof. For example, the common electrode 205 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or any suitable combination thereof. The common electrode 205 may be a transmissive electrode, a transflective electrode, or a reflective electrode.

The light-providing layer 203 may include a polymer or a low molecular weight organic material that emits light of a desired color (e.g., a predetermined color). In addition to a variety of organic materials, the light-providing layer 203 may further include one or more metal-containing compounds, such as organometallic compounds, inorganic materials such as quantum dots, and/or the like.

According to an embodiment, the light-providing layer 203 may include an emissive layer, and a first functional layer and a second functional layer respectively disposed under and over the emissive layer. The first functional layer may include, for example, a hole transport layer HTL, or may include a hole transport layer and a hole injection layer HIL. The second functional layer is an optional element disposed on the emissive layer. For example, the light-providing layer 203 may or may not include the second functional layer. The second functional layer may include an electron transport layer ETL and/or an electron injection layer EIL.

According to an embodiment, the light-providing layer 203 may include two or more emitting units (e.g., two or more light-emitting layers) sequentially stacked between the pixel electrode 201 and the common electrode 205, and a charge generating layer CGL disposed between the two emitting units. When the light-providing layer 203 includes the emitting units and the charge generating layer, the light-emitting element (e.g., the organic light-emitting diode) may have a tandem structure. The light-emitting element (e.g., the organic light-emitting diode) may improve the color purity and the emission efficiency by employing a stacked structure of a plurality of emitting units (e.g., a plurality of light-emitting layers).

One emitting unit may include an emissive layer, and a first functional layer and a second functional layer respectively disposed under and over the emissive layer. The charge generating layer CGL may include a negative-charge generating layer and a positive-charge generating layer. The emission efficiency of an organic light-emitting diode, which is a tandem light-emitting element having a plurality of emissive layers, may be further increased by the negative-charge generating layer and the positive-charge generating layer.

The negative-charge generating layer may be an n-type charge generating layer. The negative-charge generating layer may supply electrons. The negative-charge generating layer may include a host and a dopant. The host may include an organic material. The dopant may include a metal material. The positive-charge generating layer may be a p-type charge generating layer. The positive-charge generating layer may supply holes. The positive-charge generating layer may include a host and a dopant. The host may include an organic material. The dopant may include a metal material.

According to an embodiment, as shown in FIG. 14, the light-emitting element (e.g., the organic light-emitting diode) may include a first emitting unit EU1 including a first emissive layer EL1, and a second emitting unit EU2 including a second emissive layer EL2, which are stacked on one another. The charge generating layer CGL may be disposed between the first emitting unit EU1 and the second emitting unit EU2. For example, the light-emitting element (e.g., the organic light-emitting diode) may include a pixel electrode 201, a first emissive layer EL1, a charge generating layer CGL, a second emissive layer EL2, and a common electrode 205 sequentially stacked on one another. A first functional layer and a second functional layer may be disposed under and over the first emissive layer EL1, respectively. A first functional layer and a second functional layer may be disposed under and over the second emissive layer EL2, respectively. The first emissive layer EL1 may be a blue emissive layer, and the second emissive layer EL2 may be a yellow emissive layer.

According to an embodiment, as shown in FIG. 15, the light-emitting element (e.g., the organic light-emitting diode) may include a first light-emitting unit EU1 including a first emissive layer EL1, a third light-emitting unit EU3 including a first emissive layer EL1, and a second light-emitting unit EU2 including a second emissive layer EL2. The first charge generating layer CGL1 may be disposed between the first emitting unit EU1 and the second emitting unit EU2, and the second charge generating layer CGL2 may be disposed between the second emitting unit EU2 and the third emitting unit EU3. For example, the light-emitting element (e.g., the organic light-emitting diode) may include a pixel electrode 201, a first emissive layer EL1, a first charge generating layer CGL1, a second emissive layer EL2, a second charge generating layer CGL2, a first emissive layer EL1, and a common electrode 205, which are stacked on one another in this order. A first functional layer and a second functional layer may be disposed under and over the first emissive layer EL1, respectively. A first functional layer and a second functional layer may be disposed under and over the second emissive layer EL2, respectively. The first emissive layer EL1 may be a blue emissive layer, and the second emissive layer EL2 may be a yellow emissive layer.

According to an embodiment of the present disclosure, the second emitting unit EU2 of the light-emitting element (e.g., the organic light-emitting diode) may further include a third emissive layer EL3 and/or a fourth emissive layer EL4 in direct contact with the second emitting unit EU2 under and/or over the second emissive layer EL2 in addition to the second emissive layer EL2. As used herein, the phrase that the third emissive layer EL3 and/or the fourth emissive layer EL4 are in direct contact with the second emitting unit EU2 means that no other layer is disposed between the second emissive layer EL2 and the third emissive layer EL3 and/or between the second emissive layer EL2 and the fourth emissive layer EL4. The third emissive layer EL3 may be a red emissive layer, and the fourth emissive layer EL4 may be a green emissive layer.

For example, as shown in FIG. 16, the light-emitting element (e.g., the organic light-emitting diode) may include a pixel electrode 201, a first emissive layer EL1, a first charge generating layer CGL1, a third emissive layer EL3, a second emissive layer EL2, a second charge generating layer CGL2, a first emissive layer EL1, and a common electrode 205, which are stacked on one another in this order. As another example, as shown in FIG. 17, the light-emitting element (e.g., the organic light-emitting diode) may include a pixel electrode 201, a first emissive layer EL1, a first charge generating layer CGL1, a third emissive layer EL3, a second emissive layer EL2, a fourth emissive layer EL4, a second charge generating layer CGL2, a first emissive layer EL1, and a common electrode 205, which are stacked on one another in this order.

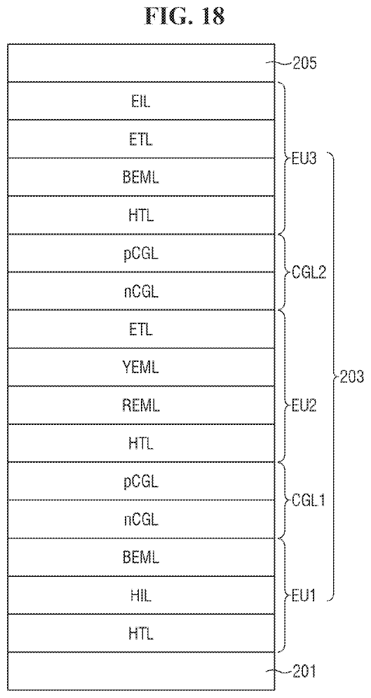

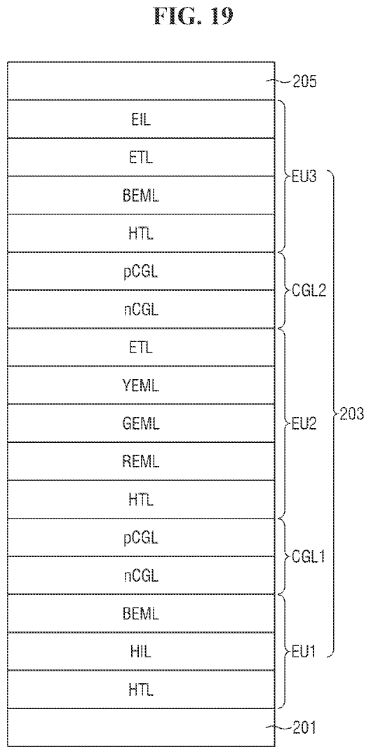

FIG. 18 is a cross-sectional view showing an example of the organic light-emitting diode of FIG. 16. FIG. 19 is a cross-sectional view showing an example of the organic light-emitting diode of FIG. 17.

Referring to FIG. 18, the light-emitting element (e.g., the organic light-emitting diode) may include a first emitting unit EU1, a second emitting unit EU2, and a third emitting unit EU3 stacked on one another in this order. The first charge generating layer CGL1 may be disposed between the first emitting unit EU1 and the second emitting unit EU2, and the second charge generating layer CGL2 may be disposed between the second emitting unit EU2 and the third emitting unit EU3. Each of the first charge generating layer CGL1 and the second charge generating layer CGL2 may include a negative-charge generating layer nCGL and a positive-charge generating layer pCGL.

The first emitting unit EU1 may include a blue emissive layer BEML. The first emitting unit EU1 may further include a hole injection layer HIL and a hole transport layer HTL between the pixel electrode 201 and the blue emissive layer BEML. According to an embodiment of the present disclosure, a p-doped layer may be further included between the hole injection layer HIL and the hole transport layer HTL. The p-doped layer may be formed by doping the hole injection layer HIL with a p-type doping material. According to an embodiment of the present disclosure, at least one of a blue light auxiliary layer, an electron blocking layer, or a buffer layer may be further included between the blue emissive layer BEML and the hole transport layer HTL. The blue light auxiliary layer may increase the emission efficiency of the blue emissive layer BEML. The blue light auxiliary layer may increase the emission efficiency of the blue emissive layer BEML by adjusting the hole charge balance. The electron blocking layer may be used to prevent or substantially prevent injection of electrons into the hole transport layer HTL. The buffer layer may be used to compensate for a resonance distance according to a wavelength of light emitted from the emissive layer.

The second emitting unit EU2 may include a yellow emissive layer YEML, and a red emissive layer REML directly in contact with the yellow emissive layer YEML under the yellow emissive layer YEML. The second emitting unit EU2 may further include a hole transport layer HTL between the positive-charge generating layer pCGL of the first charge generating layer CGL1 and the red emissive layer REML, and an electron transport layer ETL between the yellow emissive layer YEML and the negative-charge generating layer nCGL of the second charge generating layer CGL2.

The third emitting unit EU3 may include a blue emissive layer BEML. The third emitting unit EU3 may further include a hole transport layer HTL between the positive-charge generating layer pCGL of the second charge generating layer CGL2 and the blue emissive layer BEML. The third emitting unit EU3 may further include an electron transport layer ETL and an electron injection layer EIL between the blue emissive layer BEML and the common electrode 205. The electron transport layer ETL may include (e.g., may be made up of) a single layer or multiple layers. According to an embodiment of the present disclosure, at least one of a blue light auxiliary layer, an electron blocking layer, or a buffer layer may be further included between the blue emissive layer BEML and the hole transport layer HTL. At least one of the hole blocking layer or the buffer layer may be further included between the blue emissive layer BEML and the electron transport layer ETL. The hole blocking layer may be used to prevent or substantially prevent injection of holes into the electron transport layer ETL.

The light-emitting element (e.g., the organic light-emitting diode) shown in FIG. 19 is the same or substantially the same as the light-emitting element (e.g., the organic light-emitting diode) shown in FIG. 18, except for a stacked structure of a second emitting unit EU2. Referring to FIG. 19, the second emitting unit EU2 may include a yellow emissive layer YEML, a green emissive layer GEML directly in contact with the yellow emissive layer YEML under the yellow emissive layer YEML, and a red emissive layer REML directly in contact with the green emissive layer GEML under the green emissive layer GEML. The second emitting unit EU2 may further include a hole transport layer HTL between the positive-charge generating layer pCGL of the first charge generating layer CGL1 and the red emissive layer REML, and an electron transport layer ETL between the yellow emissive layer YEML and the negative-charge generating layer nCGL of the second charge generating layer CGL2.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a substrate;
a first pixel electrode and a second pixel electrode on the substrate;
a dummy pixel electrode between the first pixel electrode and the second pixel electrode, and configured to receive a dummy voltage;
an emissive layer on the first pixel electrode, the second pixel electrode, and the dummy pixel electrode; and
a common electrode on the emissive layer,
wherein the first pixel electrode is configured to receive a pixel voltage different from the dummy voltage.

2. The display device of claim 1, wherein the dummy voltage is smaller than the pixel voltage.

3. The display device of claim 2, wherein the dummy voltage is a DC voltage that is higher than a common voltage of the common electrode, and lower than a lowest grayscale level pixel voltage.

4. The display device of claim 1, further comprising a light-blocking layer overlapping with the dummy pixel electrode.

5. The display device of claim 1, wherein the dummy pixel electrode has a shape that surrounds each of the first pixel electrode and the second pixel electrode, and
wherein a portion of the dummy pixel electrode is located between the first pixel electrode and the second pixel electrode.

6. The display device of claim 5, wherein the dummy pixel electrode comprises:
a first extended portion extending in a first direction; and
a second extended portion extending in a second direction crossing the first direction.

7. The display device of claim 6, wherein the dummy pixel electrode defines a plurality of open areas surrounded by the first extended portion and the second extended portion, and
wherein the first pixel electrode and the second pixel electrode are located in the plurality of open areas.

8. The display device of claim 6, wherein at least one of the first extended portion or the second extended portion comprises:
a wide portion having a first width; and
a narrow portion having a second width smaller than the first width.

9. The display device of claim 8, wherein a dummy emission area of the dummy pixel electrode is located on the wide portion.

10. The display device of claim 1, wherein a distance between the dummy pixel electrode and the common electrode is smaller than a distance between the first pixel electrode and the common electrode.

11. The display device of claim 1, wherein a thickness of the dummy pixel electrode is greater than a thickness of the first pixel electrode.

12. The display device of claim 1, further comprising an insulating film between the substrate and the first pixel electrode, the second pixel electrode, and the dummy pixel electrode,
wherein the insulating film has a greater thickness between the substrate and the dummy pixel electrode than between the substrate and the first pixel electrode.

13. The display device of claim 1, further comprising a bank on the first pixel electrode, the second pixel electrode, and the dummy pixel electrode.

14. The display device of claim 13, wherein the bank has a first emission area, a second emission area, and a dummy emission area overlapping with the first pixel electrode, the second pixel electrode, and the dummy pixel electrode, respectively.

15. The display device of claim 14, wherein a size of the dummy emission area is smaller than a size of the first emission area.

16. The display device of claim 14, wherein the dummy emission area is located on at least one of an upper side, a lower side, a left side, or a right side of the first pixel electrode.

17. The display device of claim 14, wherein the dummy emission area has a shape that surrounds each of the first pixel electrode and the second pixel electrode.

18. The display device of claim 14, further comprising a light-blocking layer overlapping with the dummy emission area.

19. The display device of claim 14, further comprising:
a first color filter overlapping with the first emission area; and
a second color filter overlapping with the second emission area.

20. The display device of claim 1, wherein the emissive layer comprises a plurality of light-emitting units configured to emit light of different colors from each other.

21. A display device comprising:
a substrate;
a first pixel electrode and a second pixel electrode on the substrate;
a dummy pixel electrode between the first pixel electrode and the second pixel electrode;
an emissive layer on the first pixel electrode, the second pixel electrode, and the dummy pixel electrode;
a common electrode on the emissive layer; and
a light-blocking layer on the dummy pixel electrode.

22. The display device of claim 21, wherein the light-blocking layer overlaps with a dummy emission area of the dummy pixel electrode.

23. The display device of claim 21, wherein the first pixel electrode is configured to receive a pixel voltage, and the dummy pixel electrode is configured to receive a dummy voltage different from the pixel voltage.

24. The display device of claim 23, wherein the dummy voltage is smaller than the pixel voltage.

25. The display device of claim 24, wherein the dummy voltage is a DC voltage that is higher than a common voltage of the common electrode, and lower than a lowest grayscale level pixel voltage.
